(19) United States
(12) Patent Application Publication
(10) Pub. No.: US 2005/0007730 A1
(43) Pub. Date: Jan. 13, 2005

(54) Electronic apparatus

(76) Inventors: Shigeo Ohashi, Tsuchiura (JP); Yoshihiro Kondo, Tsuchiura (JP); Rintaro Minamitani, Tsuchiura (JP); Takashi Naganawa, Tsuchiura (JP); Yuuji Yoshitomi, Tsuchiura (JP); Masato Nakanishi, Tsuchiura (JP); Yasuhiko Sasaki, Tsuchiura (JP); Tsuyoshi Nakagawa, Tsuchiura (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/239,156

(22) PCT Filed: Jul. 10, 2002
(86) PCT No.: PCT/JP02/07010

(30) Foreign Application Priority Data
Nov. 12, 2001 (JP) 2001-345507

(51) Int. Cl. H05K 7/20

(52) U.S. Cl. 361/683

(57) ABSTRACT

In the structure of an electronic apparatus, in which cooling of an heat-generating element is achieved through circulation of a liquid, in particular, for providing the structure of being high in cooling performance and reliability, wherein a heat-radiation pipe 9 is connected to a heat-radiation plate 10 disposed in a rear surface of a display 2, while thermally connecting a water-cooling jacket 8 with the heat-generating element 7, thereby circulating a coolant liquid between the water-cooling jacket 8 and the heat-radiation pipe 9 by means of a liquid driving device 11. The water-cooling jacket 8 can be formed in one body of a jacket base and a flow passage therein through the die-cast forming thereof, or can be constructed in one body with the water-cooling jacket and the flow passage of piping, through connection between the jacket base and the metal pipe.

### TECHNICAL FIELD

The present invention relates to an electronic equipment or apparatus, having a device for cooling a semiconductor elements generating heat therefrom, with utilizing a circulating liquid therein.

### BACKGROUND ART

Conventional arts can be seen in, for example, Japanese Patent Laying-Open No. Hei 6-266474 (1994), and Japanese Patent Laying-Open No. Hei 7-142886 (1995), etc.

In the Japanese Patent Laying-Open No. Hei 6-266474 (1994), for example, is shown the structure of an electronic apparatus, being made up with a main housing accommodating a wiring or circuit board therein, on which a heat-generating element is mounted, and a display housing, having a display panel and being attached onto the main housing rotatably, wherein a water-cooling jacket attached onto the heat-generating element, a heat-radiation pipe, and a liquid driving mechanism are connected with one another through flexible tubes.

Further, in the Japanese Patent Laying-open No. Hei 7-142886 (1995), there is shown an example, in which the housing is made of a metal, for example, in the structure shown in the Japanese Patent Laying-Open No. Hei 6-266474 (1994).

In those examples, heat generated in the heat-generating element is transferred to the water-cooling jacket, and then the heat is transferred from the water-cooling jacket to the heat-radiation pipe by driving a liquid by means of a liquid driving mechanism, thereby being radiated into the air outside.

With such the electronic apparatuses, as being represented by a portable personal computer, etc., an increase of high heat generation by the heat-generating element (i.e., a semiconductor element) is remarkable accompanying with an improvement in performances thereof. On the other side, miniaturization or small-sizing and/or thinning in sizes of the housing is still desired or demanded, so as to be fit to be carried with.

Any one of those known prior arts mentioned above has the structure, so that the heat generated in the heat-generating element is transferred to the display side, thereby to be irradiated thereon, with respect to the high heat generation of the heat-generating element. The transfer of heat from the heat-generating element to the display side is carried out through driving a liquid between both sides. The heat transfer by means of the liquid is very preferable in efficiency, and it is suitable for the heat transfer from the element generating heat at high temperature.

However, cooling cannot be obtained fully upon the heat-generating element, when the efficiency is bad in the heat transfer from the heat-generating element to the liquid, even if being good in efficiency of the heat transfer by means of the liquid. It is also necessity to take in the consideration, reduction of the liquid within a system, due to penetration or permeation of liquid from the water-cooling jacket itself or a piping system thereof, and corrosion of the water-cooling jacket or the like, as well.

However, in the conventional arts mentioned above, the consideration is not fully taken into about the structure of the water-cooling jacket for dissolving those drawbacks mentioned above.

### DISCLOSURE OF THE INVENTION

An object is, therefore, according to the present invention, to provide an electronic apparatus, equipped with a water-cooling jacket having a good heat-transfer efficiency from the heat-generating element to a coolant liquid, and being high in a reliability thereof, in particular, in relation to the corrosion, the liquid penetration or permeation, and liquid leakage, etc.

The object mentioned above, according to the present invention, can be achieved by an electronic apparatus, comprising: a heat-receiving member being thermally connected with a heat-generating element; a heat-radiation member being connected with said heat-receiving member; and a liquid driving means being connected with said heat-receiving member and said heat-radiation member, being received within a casing, in which a coolant liquid is circulated by said liquid driving means between said heat-receiving member and said heat-radiation member, wherein said heat-receiving member has a metal plate being thermally connected with said heat-generating element, and a flow passage for said coolant liquid is formed within an inside of said metal plate.

Also, the object mentioned above, according to the present invention, can be achieved by an electronic apparatus, comprising: a heat-receiving member being thermally connected with a heat-generating element; a heat-radiation member being connected with said heat-receiving member; and a liquid driving means being connected with said heat-receiving member and said heat-radiation member, being received within a casing, in which a coolant liquid is circulated by said liquid driving means between said heat-receiving member and said heat-radiation member, wherein a flow passage of said heat-receiving member is formed with a portion of a pipe constructing a flow passage within which said coolant liquid circulates.

Further, the object mentioned above, according to the present invention, can be achieved by an electronic apparatus, comprising: a heat-receiving member being thermally connected with a heat-generating element; a heat-radiation member being connected with said heat-receiving member; and a liquid driving means being connected with said heat-receiving member and said heat-radiation member, being received within a casing, in which a coolant liquid is circulated by said liquid driving means between said heat-receiving member and said heat-radiation member, wherein said heat-receiving member has a metal plate being thermally connected with said heat-generating element, and said metal base is thermally connected with a portion of a pipe within which said coolant liquid circulates.

Also, the object mentioned above, according to the present invention, can be achieved by the electronic apparatus, as described in the above, wherein said metal base and the portion of the pipe, within which said coolant liquid circulates, are connected through a grease or an adhesive of thermo-conductive property.

Also, the object mentioned above, according to the present invention, can be achieved by the electronic apparatus, as described in the above, wherein said metal base and the portion of the pipe, within which said coolant liquid circulates, are formed in one body.

Also, the object mentioned above, according to the present invention, can be achieved by the electronic apparatus, as described in the above, wherein the portion of the pipe, within which said coolant liquid circulates, is formed in loop-like, and is thermally connected with said metal base.

Also, the object mentioned above, according to the present invention, can be achieved by the electronic apparatus, as described in the above, wherein the portion of the pipe, within which said coolant liquid circulates, is formed in a loop-like shape, directing from a center to an outer periphery thereof, by roughly bringing a central position of the loop in coincident with that of said heat-generating element, so that said coolant liquid is directed from the center to the outer periphery in direction of circulation.

Also, the object mentioned above, according to the present invention, can be achieved by the electronic apparatus, as described in the above, wherein the portion of the pipe, within which said coolant liquid circulates, is formed in such a loop-like shape, that flows within flow passages are directed opposing to each other in direction thereof, and is thermally connected with said metal base.

Also, the object mentioned above, according to the present invention, can be achieved by the electronic apparatus, as described in the above, wherein said heat-generating elements are disposed in a plural number thereof, and those plural number of the heat-generating elements are thermally connected with said heat-receiving member.

And, the object mentioned above, according to the present invention, can be achieved by the electronic apparatus, as described in the above, wherein said heat-receiving member is cooled by means of a fan.

### BRIEF DESCRIPTION OF THE DRAWINGS

FIG. 1 is a perspective view of an electronic apparatus, according to a first embodiment of the present invention;

FIGS. 2(a) and 2(b) are a front view and a A-A cross-section view of a water-cooling jacket applied in the electronic apparatus, according to the above-mentioned first embodiment of the present invention, for showing details thereof;

FIGS. 3(a) and 3(b) are a front view and a B-B cross-section view of a water-cooling jacket applied in an electronic apparatus, according to a second embodiment of the invention, and FIG. 3(c) a front view of a variation thereof, for showing details thereof;

FIG. 4 is a perspective view of an electronic apparatus, according to a third embodiment of the present invention;

FIGS. 5(a) and 5(b) are partial cross-section views of a water-cooling jacket applied in an electronic apparatus, according to a fourth embodiment of the present invention;

FIG. 6 is a partial cross-section view of a water-cooling jacket applied in an electronic apparatus, according to a fifth embodiment of the present invention;

FIG. 7 is a partial cross-section view of a water-cooling jacket applied in an electronic apparatus, according to a sixth embodiment of the present invention;

FIG. 8 is a front view of a water-cooling jacket applied in an electronic apparatus, according to a seventh embodiment of the present invention;

FIG. 9 is a front view of a water-cooling jacket applied in an electronic apparatus, according to an eighth embodiment of the present invention;

FIG. 10 is a partial cross-section view of a water-cooling jacket applied in an electronic apparatus, according to a ninth embodiment of the present invention;

FIG. 11 is a front view of a water-cooling jacket and a fan applied in an electronic apparatus, according to a tenth embodiment of the present invention; and

FIG. 12 is a front view of a water-cooling jacket and a fan applied in an electronic apparatus, according to an eleventh embodiment of the present invention.

### BEST MODE FOR CARRYING OUT THE INVENTION

An electronic apparatus, such as a so-called personal computer, includes a notebook-type personal computer, which is portable, and a desktop-type personal computer, which is mainly used on a desk. In each of those personal computers, being demanded to be high and large in processing speed and capacity thereof every year, temperature of the heat generation of a CPU, i.e., the semiconductor element, comes up to be higher, as a result of those requirements. And it is expected that this tendency will continue further in future.

On the contrary to this, in general, the personal computers are of an air-cooling type by means of a fan or the like, at the present situation. This air-cooling type has a limit in the capacity of heat-radiation, and there is a possibility that it cannot follow the heat-radiation of the CUP, which is on the tendency of high heat-generation as was mentioned in the above. However, it may be possible to treat with, by making the fan rotating with higher speed and/or large in the size thereof, but it brings about an effect against for low-noise generation and/or light-weighting, therefore it is not a realistic solution.

On the other hand, as a method for heat-radiation, to be replaced with heat-radiation of the conventional air-cooling type, there is a device for cooling the CPU by circulating a cooling medium or coolant, such as water, etc.

Such the cooling device is mainly used in a cooling system for use in a large-scaled computer, being located in a company or bank, etc., and wherein cooling water is circulated compulsively by means of a pump and is cooled down by a refrigerator for exclusive use thereof, thereby being large in the scale or sizes.

Accordingly, such the cooling device by means of the water as was mentioned above is unable, at all, to be mounted into the notebook-type personal computer, which is moved or carried with frequently, and into the desk-top personal computer, which also may be moved due to re-arrangement in an office, etc., even if this cooling device can be made small in sizes, for example.

Then, as was in the conventional arts mentioned above, various devices are studied, for achieving the cooling by means of the water, which can be mounted onto a small-sized personal computer, however the temperature of heat-generation by the semiconductor element was not so high as in the recent year, at the time when such the conventional arts were made and filed as the patent applications, therefore no personal computer equipped with such the water-cooling device comes out, as an actual product available on markets, until up to now.

On the contrary to this, according to the present invention, it is possible to achieve small-sizing of the water-cooling device, greatly, by building up the housing defining an external form of the computer main body, made of aluminum alloy or magnesium alloy, etc., being superior in heat-radiation, thereby enabling to mount the water-cooling device into the personal computer.

By the way, in order to cool down the semiconductor element within a limited space, such as inside the personal computer, it is necessary to perform cooling with a liquid medium (coolant) of a limited amount. Accordingly, it is an important object for the water-cooling device to transfer heat of the semiconductor element to a water-cooling jacket without waste.

If assuming that heat of the semiconductor element cannot be transferred to the liquid medium fully, the cooling of the semiconductor element cannot be carried out sufficiently, thereby bringing about a probability of causing thermal runaway thereof, depending on a case.

Then, according to the present invention, as a result of studying the water-cooling jacket of high heat-transfer efficiency, it is possible to obtain a water-cooling jacket, which will be explained in the following.

Hereinafter, explanation will be made on various embodiments according to the present invention, by referring to the drawings attached.

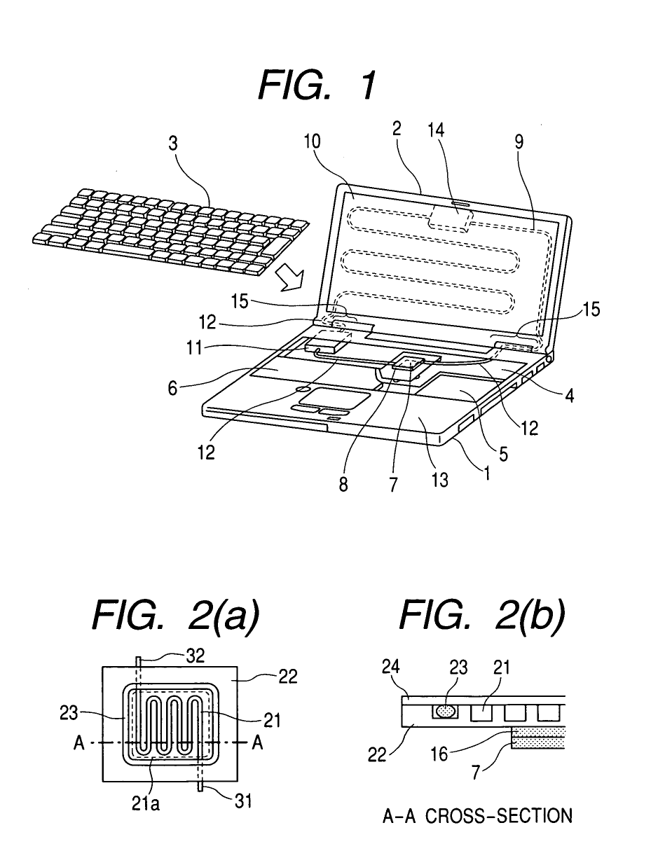

FIG. 1 shows a perspective view of an electronic apparatus, as a first embodiment according to the present invention.

In FIG. 1, the electronic apparatus is constructed with a main case 1 and a display case 2 having a display thereon, and those cases 1 and 2 are rotatable with each other through a hinge. On the main case 1 are provided a keyboard 3, a wiring or circuit board 4, on which a plural number of elements are mounted, a hard-disc drive 5, an auxiliary memory device (for example, a floppy-disc drive, a CD drive, etc.) 6, a battery 13, etc.

On the wiring or circuit board 4, there is mounted a semiconductor element, such as a central processing unit 7 (hereinafter, being described by “CPU”) having a large heat-generation amount, in particular. The CPU 7 is attached with a water-cooling jacket 8 thereon. The CPU 7 and the water-cooling jacket 8 are connected with each other, through a soft thermo-conductive material (i.e., a mixture of thermo-conductive fillers of aluminum oxide within Si robber, for example).

On a rear surface (an inner side surface of the case) of the display case 2 are provided a metal heat-radiator plate 10, on which a heat-radiation pipe 9 (being made of metal, such as copper, stainless, etc.) is connected. In an upper portion of the rear surface in the display case 2 is provided a tank 14, being connected with the heat-radiation pipe 9, and in more detail, being provided on the way of flow passage thereof. The tank 14 has such a capacity, so as to secure an amount of a liquid therein, being necessary for cooling within a circulation flow passage, even if it is lessened due to permeation thereof, or the like.

However, by making the display case 2 itself of a metal, such as aluminum alloy, magnesium alloy, etc., it may be possible to connect the heat-radiation pipe 9 directly on the display case 2, without the heat-radiation plate 10. And, a pump 11, as a liquid driving means, is provided within the main case 1.

The water-cooling jacket 8, the heat-radiation pipe 9 and the pump 11 are connected with flexible tubes 12, so that a coolant contained in an inside thereof can be circulated by means of the pump 11. The flexible tubes 12 may be used, for example, at least only in a part of the hinge portion 15.

Thus, using metal pipes in piping between the water-cooling jacket 8 and the hinge portion 15, between the pump 11 and the hinge portion 15, and between the pump 11 and the water-cooling jacket 8, while connecting the metal pipe and the heat-radiation pipe 9 by the flexible tuber 12, at least only in the portion of the hinge portion 15 can make the ratio of the metal piping portion as large as possible, occupying in the entire piping.

With this, it is possible to meet the requirement of open-close of the display portion around the hinge portion, as well as, to suppress the permeation of water from the pipe. The piping system in this case is built up, by connecting the water-cooling jacket, the flexible tube, the metal pipe, the flexible tube of the hinge portion, the heat-radiation pipe, the flexible tube of the hinge portion (the metal pipe, and the flexible tube), the pump, the flexible tube (the metal pipe, and the flexible tube), and the water-cooling jacket (the elements within the parentheses can be added).

In each of connecting portions thereof are applied an appropriate joint and a clamping band (in plate-like, or coil spring-like in the shape) for preventing from slipping off. Further, the connecting portion may be coated with a resin for the purpose of protection from leakage of water. However, as the material of the flexible tubes 12 is applied a butyl rubber, etc., such as, being less in permeation of water therethrough.

FIGS. 2(a) and 2(b) are a front view and a partial cross-section view thereof, for showing the details of the water-cooling jacket.

In the structure shown FIGS. 2(a) and 2(b), a flow passage 21 is formed within a base 22, which is made from a metal block, and is sealed with a cover 24 through an O-ring 23. As the material of the base 22 is adopted (pure) aluminum, being superior in thermo-conductivity and forming thereof, and after the forming, it is treated with an anti-corrosion processing, such as an alumite processing (or anodizing process of aluminum), etc.

The water-cooling jacket and the heat-generating element 7 are connected with each other, through a soft thermo-conductive material or member 16. It is preferable to make an outer size of the water-cooling jacket larger than that of the heat-generating element 7, and to make an area 21a forming the flow passage within the inside of the O-ring groove as large as possible. The base 22 is formed, together with the flow passage, the O-ring groove, and inlet and outlet ports 31 and 32, within the base, in one body, through the die-cast forming, etc.

Through the die-cast forming, the flow passage 21 can be formed with miniaturizing the width thereof to a limit through the die-cast forming, thereby enabling to ensure a surface area of the flow passage large. Accordingly, it is possible to improve the performance of heat transfer to the liquid flowing within the flow passage 21. Further, with miniaturizing the width of the flow passage 21, it is possible to form the flow passage 21, to have the necessary and sufficient surface area within the area, nearly equal to that of the heat-generating element 7 in the base 22, thereby reducing the thermal resistance accompanying with enlargement of the area from the heat-generating element to the area where the flow passage is formed. At the same time, also small-sizing of the water-cooling jacket can be obtained.

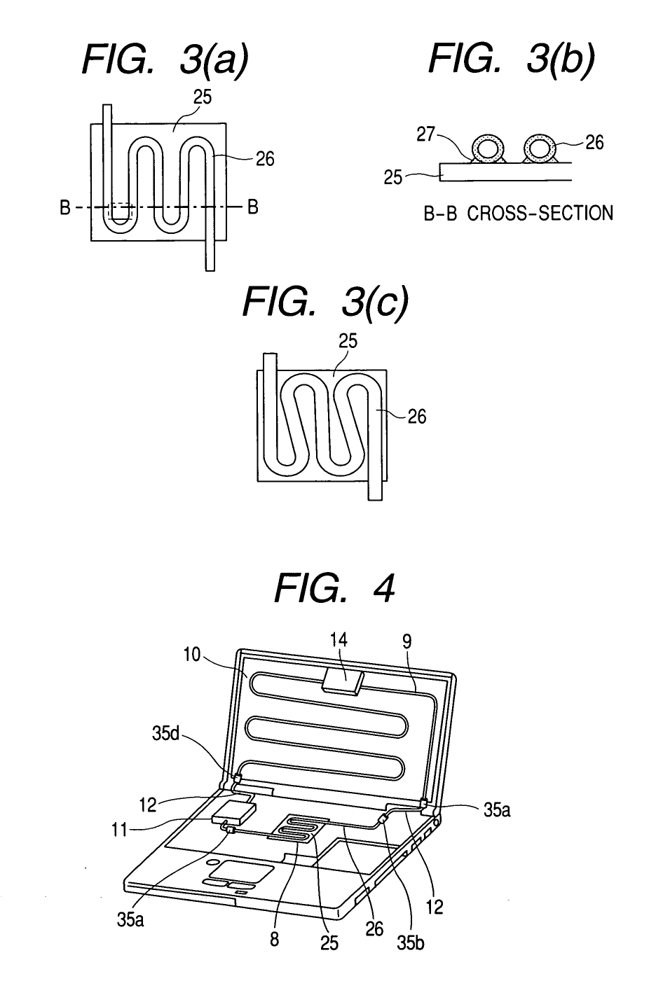

FIGS. 3(a) and 3(b) are a front view and a partial cross-section view of the water-cooling jacket, according to other (i.e., a second) embodiment of the present invention, and FIG. 3(c) a front view of a variation thereof.

In those FIGS. 3(a) and 3(b), the water-cooling jacket is built up with a flow passage made by winding or drawing a metal pipe 26, and it is bonded onto a base 25 of metal (for example, of aluminum, copper, etc.) metallically, as shown by a bonding portion 27, through the soldering or the silver-alloy brazing, in the structure thereof.

After being thermally conducted to the base 25, heat of the heat-generating element diffuses within the base 25, thereby conducted to the metal pipe 26, and it is thermally conducted into a liquid coming through an interior wall of the metal pipe 26. In this instance, it is also contributed by thermal conduction in a peripheral direction within the wall of the metal pipe 26.

Accordingly, the thermal resistance from the heat-generating element up to the liquid within the flow passage can be made small, by bonding the base 25 within the flow passage and the metal pipe, metallically, and also by bringing the metal pipe 26 to be thick in the thickness thereof while making up the metal pipe 26 of a material, being superior in thermal conductivity, such as copper, etc.

In case of forming the winding flow passage from the metal pipe 26, it is necessary to wind or bend the pipe at the minimum-bending radius, so as not to be bent or folded down. Accordingly, in order to keep length of the flow passage within the base as long as possible (i.e., to make the number of turns large), as shown in FIG. 3(c), it is also possible to bend or wind the metal pipe at the minimum bending radius being greater than 180°, so as to make the wound portions neighboring contact with.

In the present embodiment, since the structure has no such seal portion, comparing to that shown in FIGS. 2(a) and 2(b) mentioned above, reduction of the liquid will not occur due to the leakage of the liquid and/or the water permeation in the seal portion. Further, applying the material of anti-corrosion to the metal pipe 26, in the similar manner as in the heat-radiation pipe 26, negates a necessity of taking the corrosion onto the base 25 into the consideration. Also, elongating the metal pipe 26 makes up the flow passage of the water-cooling jacket, thereby bringing it to be used in common, as a part of the piping of a system as a whole, further enables a system, being less in the liquid leakage and the water permeation therein. This embodiment will be shown in FIG. 4.

FIG. 4 is a perspective view of an electronic apparatus, according a third embodiment of the present invention, in particular, in a case that flexible tubes are provided only in the hinge portions of the both cases in the structure thereof.

In FIG. 4, a portion of piping of the entire cooling system is constructed by elongating the metal pipe 26 of the flow passage, thereby to be used in the water-cooling jacket 8. Thus, in the piping between the pump 11 and the water-cooling jacket and between the water-cooling jacket 8 and the hinge portion, the metal pipe 26 is used for building up the flow passage of the water-cooling jacket. In the hinge portion, between the metal pipe 26 and the heat-radiation pipe 9, and between the pump 11 and the heat-radiation pipe 9 are connected by means of the flexible tubes 12. In the connection portion are provided joints or clamping band 35a-35d for preventing from slipping off, appropriately.

According to the present embodiment, since the ratio can be made large of the metal piping portion occupying in the entire piping large, therefore it is possible to build up a piping system being less in the leakage of the liquid and the water.

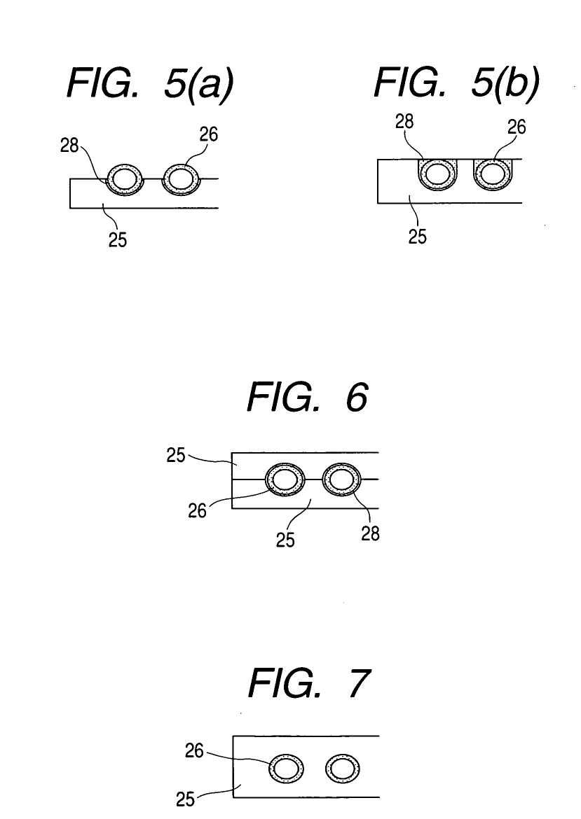

FIGS. 5(a) and 5(b) and FIG. 6 are cross-section views for showing other (i.e., a fourth and a fifth) embodiments, according to the present invention, being similar to that shown in FIG. 3 mentioned above.

In the embodiments shown in FIGS. 5(a) and 5(b) and FIG. 6, a groove 28 is formed in the base 25 made of metal (such as, aluminum, copper, etc.) along with the shape of the metal pipe 26 wound around (for example, through the die-cast forming, etc.), thereby to be fitted with the metal pipe 28 within an inside thereof. In contact portion between the metal pipe 26 and the groove 28 of the base 25 is filled up with a grease or/and an adhesive of high thermo-conductivity.

In particular, in the embodiments shown in FIG. 5(b) and FIG. 6, the contact area thereof is widen or expanded for the purpose of increasing the heat-conduction efficiency between the base 25 and the metal pipe 26, respectively, much higher than that in the structure shown in FIG. 5(a), and in particular, in FIG. 5(b), the groove 28 is deepen to be filled up with a grease or/and an adhesive of high thermo-conductivity therebetween. In FIG. 6, the metal pipe 26 is positioned between the bases 25, in each of which is formed a groove of a half (½) depth of the diameter of metal pipe 26, thereby being attached therebetween.

According to those embodiments, an advantage can be obtained that the water-cooling jacket can be manufactured with a low cost, comparing to that of metallically bonding between the metal pipe 26 and the base 25 (see FIG. 3, for example). However, because of use of the grease or/and the adhesive in the contact portion between the metal pipe 26 and the base 25, it is inferior in the performance of the thermo-conductivity. On the contrary thereto, an embodiment shown in FIG. 7 is provided for dissolving this disadvantage.

In the embodiment shown in a partial cross-section view of FIG. 7, as a sixth embodiment according to the present invention, the metal pipe 26, being wound around in a predetermined shape in advance, is cast into when forming the metal base 25 made of, such as aluminum, through the die-cast. With this method, since the metal pipe 26 and the base 25 are in contact with, completely, therefore high thermo-conductivity can be obtained without using such the grease or/and the adhesive of high thermo-conductivity.

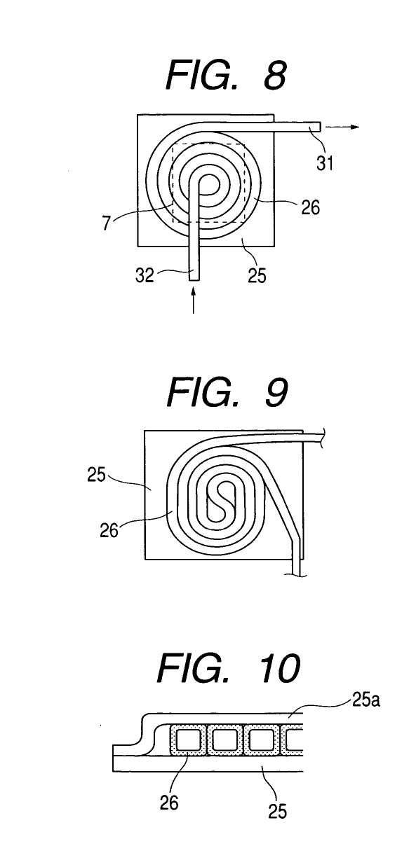

FIG. 8 is a front view of the water-cooling jacket, according to further other (i.e., a seventh) embodiment of the present invention.

The embodiment shown in FIG. 8 is constructed in combination of with the metal pipe and the metal base, in the similar manner of the embodiments shown in FIGS. 3 to 7 mentioned above.

The structure shown in FIG. 8 is that for the purpose of increasing the thermo-conductivity, from the heat-generating element 7 to the coolant, by making the length of flow passage (i.e., the surface area between the liquid flowing in a inside) as long as possible. The metal pipe 26 is formed in loop-like, and thereby being connected with the metal base 25. As a method for connection, the similar one can be applied to, shown in FIGS. 3 to 7 mentioned above.

With the present embodiment, since it is enough to make a loop radius at the center thereof being equal or larger that the minimum curvature radius to the bending, therefore the pipe can be disposed within a surface of the base 25 with high efficiency, and thereby elongating the length of flow passage. Also, disposing the central position of the loop roughly coincident with that of the heat-generating element 7, as well as, bringing the flow of liquid into a direction from 32 to 31 of the pipe, the liquid is supplied to the central portion of the heat-generating element 7 where it comes to be the highest in temperature, and therefore enabling the cooling with high efficiency.

On the other hand, the pipe 32 at an inlet side comes across the loop portion of the pipe. Therefore, the height in the flow passage portion of the water-cooling jacket must be two (2) times large as the diameter of the pipe. On the contrary to this, an embodiment shown in FIG. 9 is formed with a pipe in such a loop shape, that the height is same at the inlet side and the outlet side of the flow passage.

Thus, FIG. 9 shows a front view of the water-cooling jacket, according to other (i.e., an eight) embodiment of the present invention.

According to that shown in FIG. 9, the pipe 26 is disposed in an ellipse-like within the base 25, differing from that shown in FIG. 8, and this enables the length of flow passage to be long, as well as, to direct the flow directions in opposite within the pipes neighboring to each other.

Accordingly, it is possible to obtain a high cooling efficiency. Furthermore, the water-cooling jacket can be made thin in the thickness, since the pipe can be so disposed that, the height of the flow passage is same at the inlet side and the outlet side thereof.

However, the pipe 26 may be formed, as is shown in FIG. 10, i.e., nearly equal to a square or quadrangular in the cross-section shape thereof, being flat on both upper and lower surfaces of the pipe through the press, thereby being connected on the base 25 of a flat plate, directly. In FIG. 10, further a plate 25a is provided in an upper portion, thereby fixing the pipe 26, by putting it between the base 25 and the plate 25a.

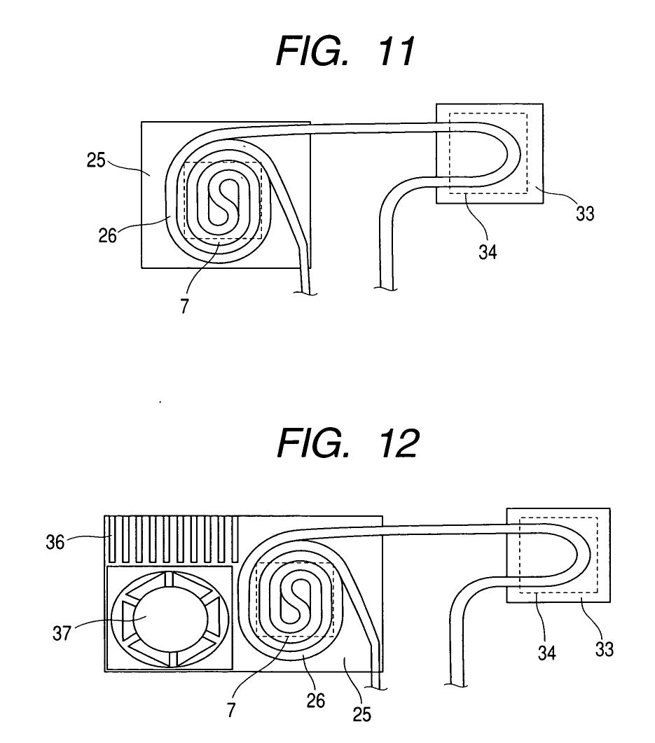

FIG. 11 is a front view for showing other (i.e., a tenth) embodiment according to the present invention, being similar to that shown in the above-mentioned FIG. 9.

In FIG. 11, the pipe 26 is elongated, which makes up the water-cooling jacket (being similar to the embodiment shown in FIG. 9 mentioned above) for cooling the heat-generating element 7, so as to be connected with a second base plate 33. This second base plate 33 is in contact with a second heat-generating element 34, thereby cooling down the second heat-generating element 34 with the similar structure (it may be any structure of the embodiments mentioned above) and the mechanism (or the manner) of cooling the heat-generating element 7. Further, the base plate 25 and the second base plate 33 may be formed in one body, to be connected with the plural number of heat-generating elements 7 and 34. According to the present structure, the plural number of heat-generating elements can be cooled by the flow passage formed in one body.

FIG. 12 is a front view for showing the water-cooling jacket, according to further other (i.e., an eleventh) embodiment of the present invention.

In FIG. 12, with the water-cooling jacket for cooling the heat-generating element 7 is further added a compulsive air-cooling structure, by means of a fan 37, in the combination therewith. On the base plate 25 in contact with the heat-generating element 7, a fin 36 is attached, and further provided the fan 37. This fan 37 sucks the air from the above plane (in the direction perpendicular to the sheet surface of the drawing), for example, and discharges the air from a side surface of the fan 37 towards the fin 36. Also, the fin 36 may be formed on the plate 25a, which holds the pipe 26 therebetween as shown in FIG. 10 mentioned above, thereby cooling the pipe 26 directly and compulsively.

According to the present embodiment, although the case is shown where the plural number of heat-generating elements 7 and 34 are cooled down, by using the base plates 25 and 33, separately, in the similar manner to the embodiment shown in FIG. 11 mentioned above, however it may be the structure without providing such the second base plate 26, or may be the structure, in which the cooling by means of the fan 37 is combined with the structure for cooling the plural number of the heat-generating elements 7 and 34 on the base plate 25 and the second base plate 33, which are formed in one body.

According to the present embodiment, since further the compulsive cooling by means of the fan is added to the cooling of thermally transferring the heat of the heat-generating element through circulation of the coolant liquid to the heat-radiation plate, to radiate heat therefrom, therefore high performance of cooling can be obtained.

However, all the embodiments shown in FIGS. 1 to 12 mentioned above show the case of being applied only to the notebook-type personal computer, however they may be applied to a computer of other type than this and/or other electronic apparatuses or appliances, as well.

As was mentioned in the above, the heat generated from the heat-generating element is transferred to the coolant liquid flowing within the water-cooling jacket, and is radiated from the heat-radiation plate provided on a rear surface of the display through the surface of the display case into the air outside, during the time when it passes through the heat-radiation pipe.

With this, the coolant liquid lowered in temperature thereof is sent out to the water-cooling jacket, again, through the liquid driving device. The heat-conducting route from the heat-generating element to the liquid includes: the heat conduction from the heat-generating element to the water-cooling jacket; the heat diffusion into the area where the flow passage is formed within the base; and the heat conduction from the area where the flow passage is formed to the liquid flowing within the flow passage.

The die-cast forming of the flow passage within the water-cooling jacket enables the flow passage to be formed within the base, being formed in an area nearly equal to the heat-generating element and having a sufficient surface area, thereby reducing the thermal resistance accompanying with an increase of area in the area where the flow passage is formed within the jacket base. Also, connection of the jacket base and the metal pipe for forming the flow passage can be obtained in the piping, thereby forming the flow passage in the water-cooling jacket by means of the metal pipe, can achieves the structure without no seal portion therein, i.e., no permeation of the liquid. In the case of the present structure, with using the pipe of a metal material of anti-corrosion in the flow passage of the piping, it is also possible to suppress the corrosion in the water-cooling jacket.

### INDUSTRIAL APPLICABILITY

As was fully mentioned in the above, according to the present invention, it is possible to provide an electronic apparatus equipped with a water-cooling jacket, being superior in thermal conduction efficiency from the heat-generating element to the coolant liquid and being high in reliability to the corrosion, the liquid permeation, and the liquid leakage, as well.

1. An electronic apparatus, comprising:
a heat-receiving member being thermally connected with a heat-generating element;
a heat-radiation member being connected with said heat-receiving member; and
a liquid driving means being connected with said heat-receiving member and said heat-radiation member, being received within a casing, in which a coolant liquid is circulated by said liquid driving means between said heat-receiving member and said heat-radiation member, wherein said heat-receiving member has a metal plate being thermally connected with said heat-generating element, and a flow passage for said coolant liquid is formed within an inside of said metal plate.

2. An electronic apparatus, comprising:
a heat-receiving member being thermally connected with a heat-generating element;
a heat-radiation member being connected with said heat-receiving member; and
a liquid driving means being connected with said heat-receiving member and said heat-radiation member, being received within a casing, in which a coolant liquid is circulated by said liquid driving means between said heat-receiving member and said heat-radiation member, wherein a flow passage of said heat-receiving member is formed with a portion of a pipe constructing a flow passage within which said coolant liquid circulates.

3. An electronic apparatus, comprising:
a heat-receiving member being thermally connected with a heat-generating element;
a heat-radiation member being connected with said heat-receiving member; and
a liquid driving means being connected with said heat-receiving member and said heat-radiation member, being received within a casing, in which a coolant liquid is circulated by said liquid driving means between said heat-receiving member and said heat-radiation member, wherein said heat-receiving member has a metal plate being thermally connected with said heat-generating element, and said metal base is thermally connected with a portion of a pipe within which said coolant liquid circulates.

4. An electronic apparatus, as described in the claim 3, wherein said metal base and the portion of the pipe, within which said coolant liquid circulates, are connected through a grease or an adhesive of thermo-conductive property.

5. An electronic apparatus, as described in the claim 3, wherein said metal base and the portion of the pipe, within which said coolant liquid circulates, are formed in one body.

6. An electronic apparatus, as described in the claim 3, wherein the portion of the pipe, within which said coolant liquid circulates, is formed in loop-like, and is thermally connected with said metal base.

7. An electronic apparatus, as described in the claim 3, wherein the portion of the pipe, within which said coolant liquid circulates, is formed in a loop-like shape, directing from a center to an outer periphery thereof, by roughly bringing a central position of the loop in coincident with that of said heat-generating element, so that said coolant liquid is directed from the center to the outer periphery in direction of circulation.

8. An electronic apparatus, as described in the claim 3, wherein the portion of the pipe, within which said coolant liquid circulates, is formed in such a loop-like shape, that flows within flow passages are directed opposing to each other in direction thereof, and is thermally connected with said metal base.

9. An electronic apparatus, as described in the claim 1, wherein said heat-generating elements are disposed in a plural number thereof, and those plural number of the heat-generating elements are thermally connected with said heat-receiving member.

10. An electronic apparatus, as described in the claim 2, wherein said heat-generating elements are disposed in a plural number thereof, and those plural number of the heat-generating elements are thermally connected with said heat-receiving member.

11. An electronic apparatus, as described in the claim 3, wherein said heat-generating elements are disposed in a plural number thereof, and those plural number of the heat-generating elements are thermally connected with said heat-receiving member.

12. An electronic apparatus, as described in the claim 1, wherein said heat-receiving member is cooled by means of a fan.

13. An electronic apparatus, as described in the claim 2, wherein said heat-receiving member is cooled by means of a fan.

14. An electronic apparatus, as described in the claim 3, wherein said heat-receiving member is cooled by means of a fan.
